(19) United States
(12) Patent Application Publication
(10) Pub. No.: US 2026/0150208 A1
(43) Pub. Date: May 28, 2026

(54) TRANSFORMABLE DATA STORAGE APPARATUS

(71) Applicant: Fang CHAO, Zhuhai City (CN)

(72) Inventor: Fang CHAO, Zhuhai City (CN)

(21) Appl. No.: 18/969,239

(22) Filed: Dec. 4, 2024

(30) Foreign Application Priority Data
Nov. 25, 2024 (CN) 202422879700.4

(51) Int. Cl. H05K 5/02

(52) U.S. Cl. CPC H05K 5/0234; H05K 5/0243

(57) ABSTRACT

A transformable data storage apparatus includes a data storage system, an accommodating housing and an appendage system. The data storage system is responsible for recording and storing various types of data in a specific coded format. The accommodating space is configured to accommodate the data storage system. The appendage system is rotatably connected to the accommodating housing. The appendage system has an unfolded state and a stored state. When the appendage system is in the stored state, the appendage system is folded and contracted. When the appendage system is in the unfolded state, the transformable data storage apparatus has a decorative function. Through the arrangement of the above structure, during use, the apparatus can be used as a data storage tool and become a decorative object that with a decorative value. Thereby increasing the aesthetic value and enhancing the personalized feature of the apparatus.

### TECHNICAL FIELD

The present disclosure relates to the technical field of data storage apparatuses, and in particular, to a transformable data storage apparatus.

### BACKGROUND OF THE INVENTION

With the development of society, people not only enjoy material life, but also constantly pursue spiritual life. More and more people like to use various data storage apparatuses. The data storage apparatuses are easy to use, but users usually place the data storage apparatuses in storage spaces such as drawers when the data storage apparatuses are not in use. If a data storage apparatus placed in the storage space such as the drawer is not used for a long time, it is easy to forget the specific placement position. As a result, the data storage apparatus cannot be found in time when needed. When a user suddenly has an urgent data usage requirement and is in an urgent need of a specific data storage apparatus, the user often feels anxious and helpless because the user cannot quickly remember an exact position of the specific data storage apparatus in the drawer. The user may spend a lot of time rummaging through drawers, and may even find nothing after searching through all possible drawers. This seriously affects the usage efficiency, and work or another important transaction is put off being processed due to a failure of obtaining some important data in time.

Therefore, most users sincerely hope to have a new type of data storage apparatus that does not need to be placed in a storage space such as a drawer in the traditional way when not in use, thereby effectively avoiding many inconveniences caused by forgetting a placement position. This data storage apparatus can be quickly found and put into use when a user needs to use it, which really achieves a perfect combination of high usage efficiency and convenience of use of the data storage apparatus, so as to better meet strict requirements of people for data management in modern fast-paced living and working environments.

Therefore, the present disclosure provides a transformable data storage apparatus with a simple structure. When not in use, the transformable data storage apparatus can be used as a decoration on a desktop or as a toy. This can effectively solve the above-mentioned problems.

### SUMMARY OF THE INVENTION

In order to overcome the shortcomings of the prior art, the present disclosure provides a transformable data storage apparatus with a simple structure. When not in use, the transformable data storage apparatus can be used as a decoration on a desktop or as a toy.

The technical solution adopted by the present disclosure to solve the technical problem is as follows.

A transformable data storage apparatus, includes: a data storage system, wherein the data storage system includes a storage unit and an interface unit; the storage unit is electrically connected to the interface unit; the storage unit is configured to store data; the data storage system is connected to an external device through the interface unit; an accommodating housing, wherein the accommodating housing includes a top wall, a bottom wall, and side walls; the side walls include a first side wall, a second side wall, a third side wall, and a fourth side wall; the first side wall is opposite to the second side wall, and the third side wall is opposite to the fourth side wall; the top wall, the bottom wall, and the side walls jointly define an accommodating space; the accommodating space is configured to accommodate the data storage system; and an appendage system, wherein the appendage system is rotatably connected to the accommodating housing; the appendage system has an unfolded state and a stored state; when the appendage system is in the stored state, the appendage system is folded and contracted; and when the appendage system is in the unfolded state, the transformable data storage apparatus has a decorative function.

As an improvement of the present disclosure, the data storage system is a semiconductor storage system, and the storage unit is a semiconductor chip.

As an improvement of the present disclosure, the first side wall is provided with a side wall opening; a size of the side wall opening corresponds to the interface unit; and the interface unit is threaded out of the first side wall through the opening.

As an improvement of the present disclosure, the transformable data storage apparatus further includes a protective cover body, the protective cover body is configured to protect the interface unit.

As an improvement of the present disclosure, the appendage system includes a first appendage assembly and a second appendage assembly; the first appendage assembly is rotatably connected to the side walls; and the first appendage assembly is rotatably connected to the side walls.

As an improvement of the present disclosure, the first appendage assembly includes a first appendage and a second appendage; the first appendage is arranged on the third side wall; and the second appendage is arranged on the fourth side wall.

As an improvement of the present disclosure, the second appendage assembly includes a third appendage and a fourth appendage; the third appendage is arranged at a first end of the second side wall; and the fourth appendage is arranged at a second end of the second side wall.

As an improvement of the present disclosure, the transformable data storage apparatus further includes a tail assembly; and the tail assembly is mounted between the first end and the second end of the second side wall.

As an improvement of the present disclosure, the tail assembly includes a tail mounting member and a tail piece; the tail mounting member is fixedly connected to the second side wall; and the tail piece is rotatably connected to the tail mounting member.

As an improvement of the present disclosure, the first appendage includes a first connector; the second appendage includes a second connector; the third appendage includes a third connector; the fourth appendage includes a fourth connector; the first appendage is rotatably connected to the third side wall through the first connector; the second appendage is rotatably connected to the fourth side wall through the second connector; the third appendage is rotatably connected to the second side wall through the third connector; and the fourth appendage is rotatably connected to the second side wall through the fourth connector.

As an improvement of the present disclosure, a rotation center line of the first connector is a first center line; a rotation center line of the second connector is a second center line; and the first center line approximately overlaps the second center line.

As an improvement of the present disclosure, a rotation center line of the third connector is a third center line; a rotation center line of the fourth connector is a fourth center line; and the third center line is approximately parallel to the fourth center line.

As an improvement of the present disclosure, the third center line is approximately perpendicular to the first center line and the second center line; and the fourth center line is approximately perpendicular to the first center line and the second center line.

As an improvement of the present disclosure, the first appendage further includes a first leg piece; the second appendage further includes a second leg piece; the third appendage further includes a third leg piece; the fourth appendage further includes a fourth leg piece; the first leg piece is rotatably connected to the first connector; the second leg piece is rotatably connected to the first connector; the third leg piece is rotatably connected to the third connector; and the fourth leg piece is rotatably connected to the fourth connector.

As an improvement of the present disclosure, a plane where the first leg piece is located always remains approximately perpendicular to the first center line during rotation; a plane where the second leg piece is located always remains approximately perpendicular to the second center line during rotation; and the first appendage always remains approximately parallel to a plane where the first appendage is located.

As an improvement of the present disclosure, a plane where the third leg piece is located always remains approximately parallel to the third center line during rotation, and a plane where the fourth leg piece is located always remains approximately parallel to the fourth center line during rotation.

As an improvement of the present disclosure, a spatial degree of freedom of the second appendage assembly is greater than a spatial degree of freedom of the first appendage assembly.

As an improvement of the present disclosure, a spatial degree of freedom of the first leg piece is equal to a spatial degree of freedom of the second leg piece.

As an improvement of the present disclosure, a spatial degree of freedom of the third leg piece is equal to a spatial degree of freedom of the fourth leg piece.

As an improvement of the present disclosure, the spatial degree of freedom of the first leg piece is less than the spatial degree of freedom of the third leg piece.

Beneficial effects: Through the arrangement of the above structure, during use, the storage unit is used as a core data storage component of the entire apparatus, and is responsible for recording and storing various types of data in a specific coded format, such as various types of file information including documents, images, audios, videos, and games. This causes a user to save important data resources in a long-term and stable manner, and needs for data storage and calling in different scenarios are met. The interface unit is used as a bridge between the data storage system and an external device. On the one hand, the interface unit allows the external device such as a television, a computer, a mobile phone, and a tablet to transmit data to the storage unit for storage. On the other hand, when the user needs to use the data stored in the apparatus, the interface unit can accurately and quickly transmit the data in the storage unit to the external device for reading, editing, playing, and other operations, thereby ensuring the flowing and availability of the data between different devices, and greatly expanding an application scope and use flexibility of the data storage apparatus. The top wall, the bottom wall, and the side walls form a relatively enclosed and independent accommodating space. The accommodating space provides physical protection for the data storage system. It can effectively block external adverse factors such as dust, water vapor, and minor collisions from causing damage to the internal fragile storage unit and interface unit, thereby ensuring normal operation of the data storage apparatus and the security of the data. Meanwhile, the accommodating housing further provides a regular outline structure for the entire apparatus, making it easy for the user to hold and place the apparatus and match the apparatus with other devices or environments. When the appendage system is in the stored state of being folded and contracted, a main function of the appendage system is to reduce a space occupied by the overall volume of the apparatus, so that the data storage apparatus is more convenient and compact during storage or carrying, and an inconvenience or collision damage to the data storage apparatus due to a protruding appendage structure is avoided. This storage design allows the apparatus to better adapt to different storage environments such as a pocket and a bag, thereby improving the portability of the apparatus. When the appendage system is in the unfolded state, the appendage system endows the transformable data storage apparatus with a decorative function. This not only increases the aesthetics and artistry of the apparatus, so that the apparatus can be used as a data storage tool and become a decorative object that with a decorative value. The data storage apparatus can be better integrated with a surrounding environment such as home decoration and office desktop layout, thereby increasing the aesthetic value and enhancing the personalized feature of the apparatus. In addition, in some specific scenarios, such as in a show, an exhibition, or as a gift, the unfolded appendage system can attract more attentions and show a unique design charm, thereby expanding functional boundaries of the data storage apparatus, making the data storage apparatus not limited to practical functions of data storage and transmission and have beautifying and exhibition functions. This meets a need of the user for diversified functions of a product and a usage expectation in different scenarios.

### BRIEF DESCRIPTION OF DRAWINGS

In order to explain the technical solutions of the embodiments of the present disclosure more clearly, the following will briefly introduce the accompanying drawings used in the embodiments. The drawings in the following description are only some embodiments of the present disclosure. Those of ordinary skill in the art can obtain other drawings based on these drawings without creative work. In addition, the accompanying drawings are not drawn to a scale of 1:1, and the relative dimensions of the various elements are only shown as examples in the diagrams, not necessarily drawn to a true scale.

The present disclosure is further described below in detail in combination with the accompanying drawings and embodiments.

FIG. 1 is a schematic diagram of an entire structure of a transformable data storage apparatus in a stored state according to the present disclosure, viewed in a first visual field;

FIG. 2 is a schematic diagram of an entire structure of a transformable data storage apparatus in a stored state according to the present disclosure, viewed in a first visual field;

FIG. 3 is a schematic diagram of a sectional structure of a transformable data storage apparatus according to the present disclosure;

FIG. 4 is a schematic diagram of an entire structure of a transformable data storage apparatus in an unfolded state according to the present disclosure, viewed in a first visual field;

FIG. 5 is a schematic diagram of an entire structure of a transformable data storage apparatus in an unfolded state according to the present disclosure, viewed in a second visual field;

FIG. 6 is a schematic exploded structural diagram of a transformable data storage apparatus in a stored state according to the present disclosure, viewed in a first visual field;

FIG. 7 is a schematic exploded structural diagram of a transformable data storage apparatus in a stored state according to the present disclosure, viewed in a second visual field;

FIG. 8 is a schematic exploded structural diagram of a transformable data storage apparatus in an unfolded state according to the present disclosure, viewed in a first visual field;

FIG. 9 is a schematic exploded structural diagram of a transformable data storage apparatus in an unfolded state according to the present disclosure, viewed in a second visual field; and

FIG. 10 is a schematic exploded structural diagram of a transformable data storage apparatus in an unfolded state according to the present disclosure, viewed in a third visual field.

### DETAILED DESCRIPTION OF THE INVENTION

To make the aforementioned objectives, features, and advantages of the present disclosure more comprehensible, specific implementations of the present disclosure are described in detail below in conjunction with the accompanying drawings. In the following description, numerous specific details are set forth to provide a thorough understanding of the present disclosure. The present disclosure may, however, be embodied in many forms different from that described here. A person skilled in the art can make similar improvements without departing from the connotation of the present disclosure. Therefore, the present disclosure is not limited by the specific embodiments disclosed below.

In the description of the present disclosure, It is to be understood that, The terms “center”, “longitudinal”, “transverse”, “upper”, “lower”, “front”, “rear”, “left”, “right”, “vertical”, “horizontal”, “top”, “bottom”, “inner”, “outer”, “clockwise”, “counterclockwise”, and the like indicate azimuth or positional relationships based on the azimuth or positional relationships shown in the drawings, For purposes of convenience only of describing the present disclosure and simplifying the description, Rather than indicating or implying that the indicated device or element must have a particular orientation, be constructed and operated in a particular orientation, therefore, not to be construed as limiting the present disclosure.

In addition, the terms “first” and “second” are used for descriptive purposes only, while not to be construed as indicating or implying relative importance or implicitly specifying the number of technical features indicated thereby, features defining “first,” “second,” and “second” may explicitly or implicitly include one or more of the described features. In the description of the present disclosure, “multiple” means two or more unless explicitly specified otherwise.

In addition, the terms “install”, “arrange”, “provide”, “connect” and “couple” should be understood broadly. For example, it can be a fixed connection, a detachable connection, an integral structure, a mechanical connection, an electrical connection, a direct connection, an indirect connection through an intermediate medium, or a communication between two devices, elements or components. For ordinary technical personnel in this field, the specific meanings of the above terms in present disclosure can be understood based on specific circumstances.

In the present disclosure, unless specific regulation and limitation otherwise, the first feature “onto” or “under” the second feature may include the direct contact of the first feature and the second feature, or may include the contact of the first feature and the second feature through other features between them instead of direct contact. Moreover, the first feature “onto”, “above” and “on” the second feature includes that the first feature is right above and obliquely above the second feature, or merely indicates that the horizontal height of the first feature is higher than the second feature. The first feature “under”, “below” and “down” the second feature includes that the first feature is right above and obliquely above the second feature, or merely indicates that the horizontal height of the first feature is less than the second feature.

It should be noted that when an element is referred to as being “fixed to” another element, the element can be directly on another component or there can be a centered element. When an element is considered to be “connected” to another element, the element can be directly connected to another element or there may be a centered element. The terms “inner”, “outer”, “left”, “right”, and similar expressions used herein are for illustrative purposes only and do not necessarily represent the only implementation.

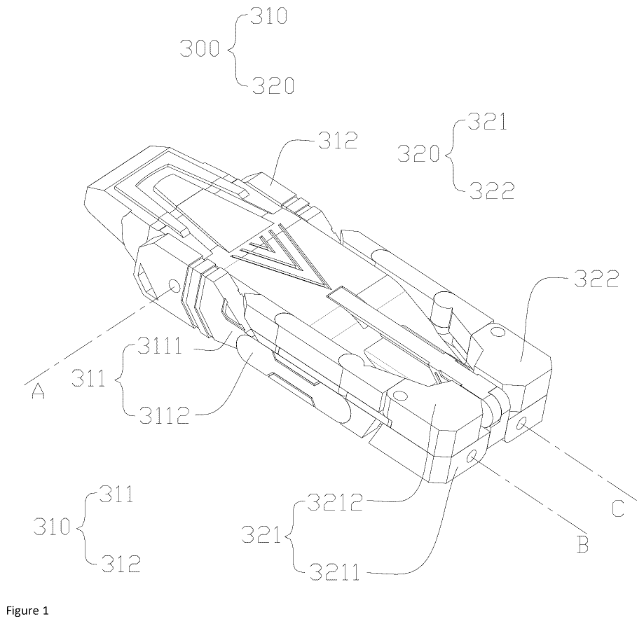

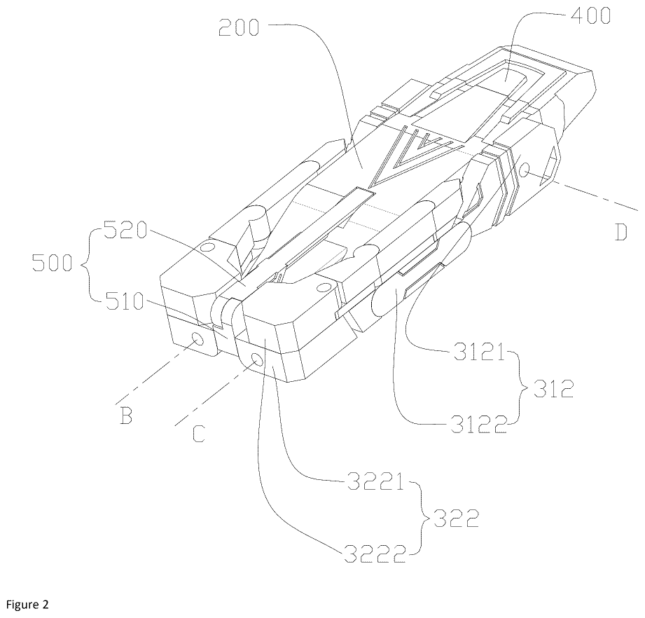

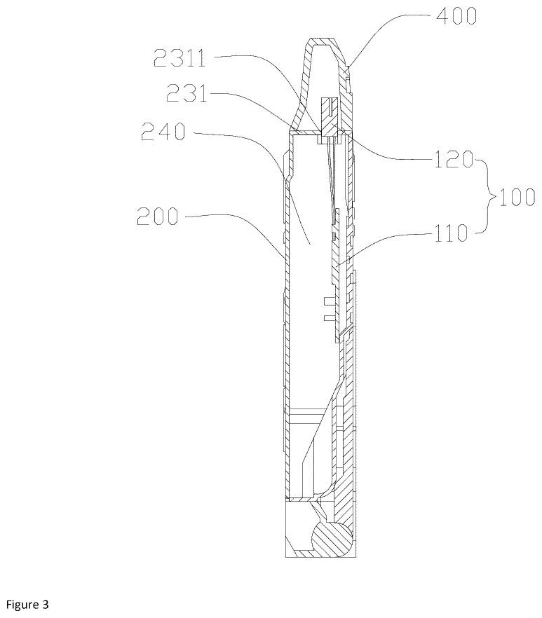

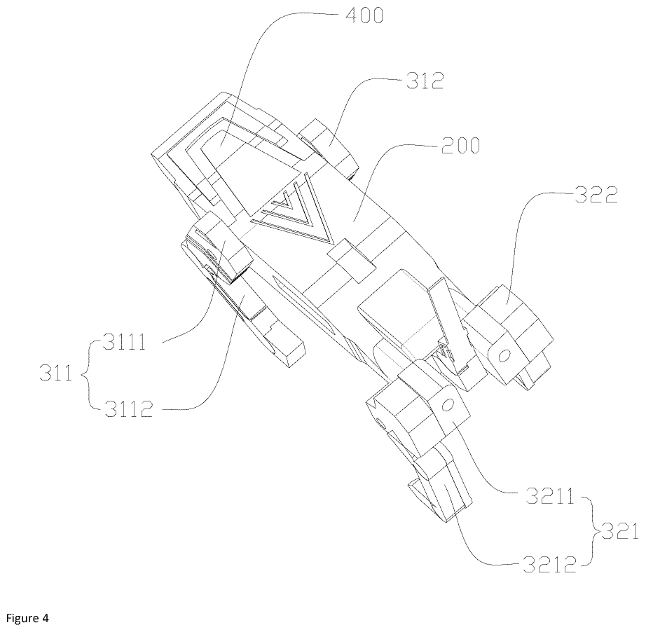

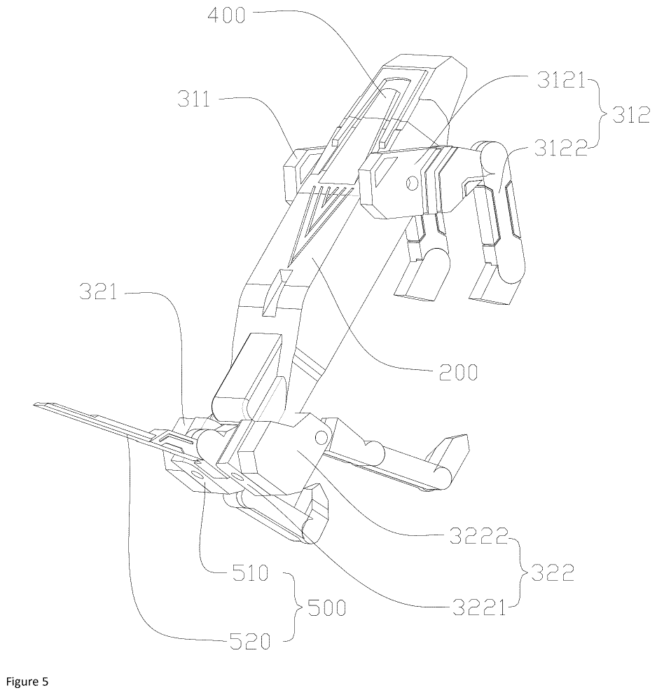

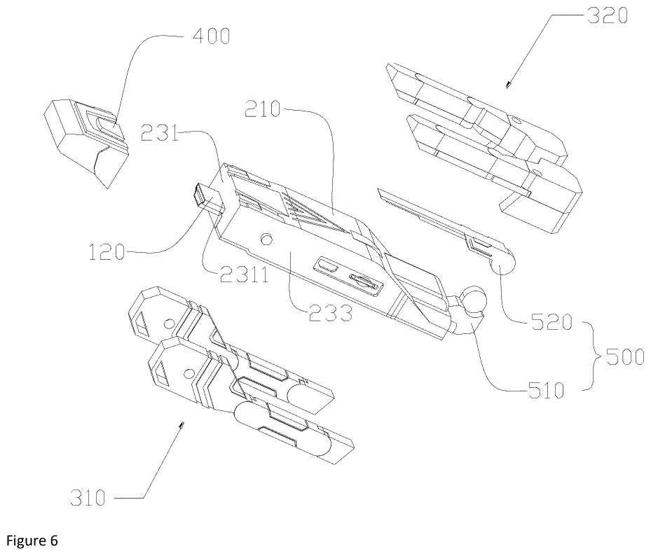

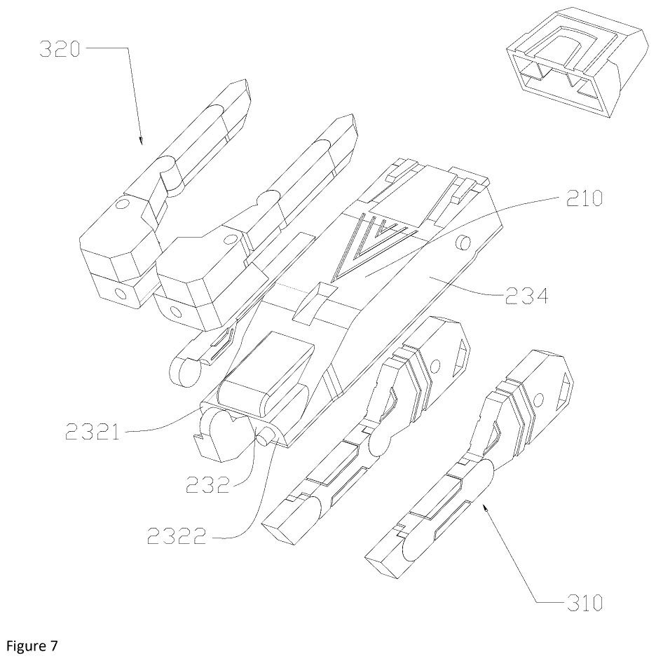

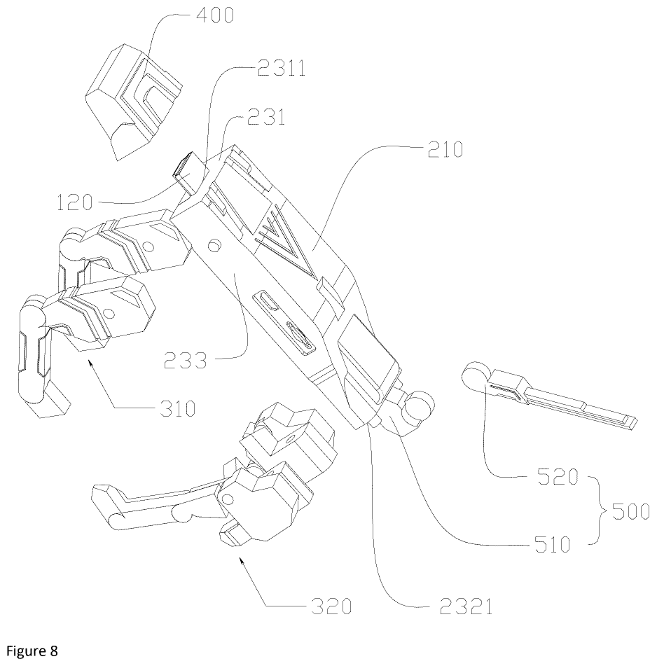

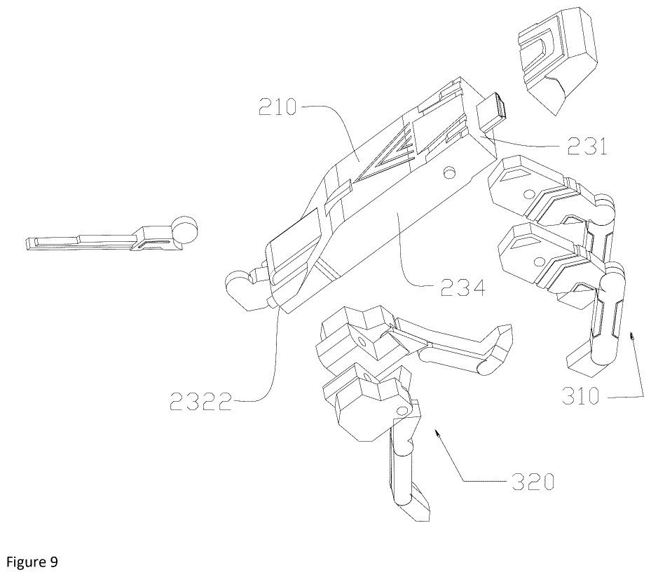

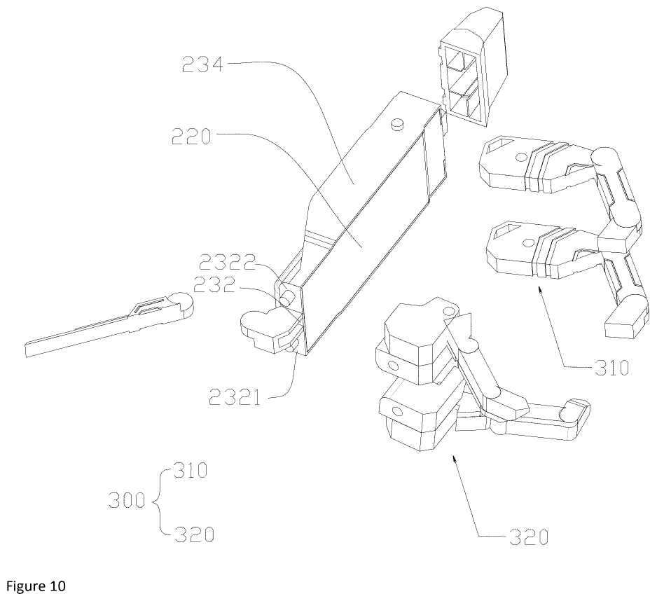

Referring to FIG. 1 to FIG. 10, a transformable data storage apparatus includes: a data storage system 100, wherein the data storage system 100 includes a storage unit 110 and an interface unit 120; the storage unit 110 is electrically connected to the interface unit 120; the storage unit 110 is configured to store data; the data storage system 100 is connected to an external device through the interface unit 120; an accommodating housing 200, wherein the accommodating housing 200 includes a top wall 210, a bottom wall 220, and side walls 230; the side walls 230 include a first side wall 231, a second side wall 232, a third side wall 233, and a fourth side wall 234; the first side wall 231 is opposite to the second side wall 232, and the third side wall 233 is opposite to the fourth side wall 234; the top wall 210, the bottom wall 220, and the side walls 230 jointly define an accommodating space 240; the accommodating space 240 is configured to accommodate the data storage system 100; and an appendage system 300, wherein the appendage system 300 is rotatably connected to the accommodating housing 200; the appendage system 300 has an unfolded state and a stored state; when the appendage system 300 is in the stored state, the appendage system 300 is folded and contracted; and when the appendage system 300 is in the unfolded state, the transformable data storage apparatus has a decorative function.

Through the arrangement of the above structure, during use, the storage unit 110 is used as a core data storage component of the entire apparatus, and is responsible for recording and storing various types of data in a specific coded format, such as various types of file information including documents, images, audios, videos, and games. This causes a user to save important data resources in a long-term and stable manner, and needs for data storage and calling in different scenarios are met. The interface unit 120 is used as a bridge between the data storage system 100 and an external device. On the one hand, the interface unit allows the external device such as a television, a computer, a mobile phone, and a tablet to transmit data to the storage unit for storage. On the other hand, when the user needs to use the data stored in the apparatus, the interface unit can accurately and quickly transmit the data in the storage unit to the external device for reading, editing, playing, and other operations, thereby ensuring the flowing and availability of the data between different devices, and greatly expanding an application scope and use flexibility of the data storage apparatus. The top wall 210, the bottom wall 220, and the side walls 230 form a relatively enclosed and independent accommodating space 240. The accommodating space 240 provides physical protection for the data storage system 100. It can effectively block external adverse factors such as dust, water vapor, and minor collisions from causing damage to the internal fragile storage unit and interface unit, thereby ensuring normal operation of the data storage apparatus and the security of the data. Meanwhile, the accommodating housing 200 further provides a regular outline structure for the entire apparatus, making it easy for the user to hold and place the apparatus and match the apparatus with other devices or environments. When the appendage system 300 is in the stored state of being folded and contracted, a main function of the appendage system 300 is to reduce a space occupied by the overall volume of the apparatus, so that the data storage apparatus is more convenient and compact during storage or carrying, and an inconvenience or collision damage to the data storage apparatus due to a protruding appendage structure is avoided. This storage design allows the apparatus to better adapt to different storage environments such as a pocket and a bag, thereby improving the portability of the apparatus. When the appendage system 300 is in the unfolded state, the appendage system 300 endows the transformable data storage apparatus with a decorative function. This not only increases the aesthetics and artistry of the apparatus, so that the apparatus can be used as a data storage tool and become a decorative object that with a decorative value. The data storage apparatus can be better integrated with a surrounding environment such as home decoration and office desktop layout, thereby increasing the aesthetic value and enhancing the personalized feature of the apparatus. In addition, in some specific scenarios, such as in a show, an exhibition, or as a gift, the unfolded appendage system 300 can attract more attentions and show a unique design charm, thereby expanding functional boundaries of the data storage apparatus, making the data storage apparatus not limited to practical functions of data storage and transmission and have beautifying and exhibition functions. This meets a need of the user for diversified functions of a product and a usage expectation in different scenarios.

In this embodiment, the data storage system 100 is a semiconductor storage system, and the storage unit 110 is a semiconductor chip. Through the arrangement of the above structure, the semiconductor storage system can quickly respond to a data request of the external device such as a computer because it uses an electrical signal to control data reading and writing, without a delay of a mechanical component. This makes data reading and writing almost instantaneous, so that the usage efficiency of the data storage apparatus is greatly improved.

In this embodiment, the first side wall 231 is provided with a side wall opening 2311. A size of the side wall opening 2311 corresponds to the interface unit 120. The interface unit 120 is threaded out of the first side wall 231 through the opening. Through the arrangement of the above structure, during use, since the size of the side wall opening 2311 corresponds to the interface unit 120, it ensures that the interface unit can tightly abut against an edge of the opening when being threaded out of the first side wall. On the one hand, it can prevent the interface unit from shaking randomly during use, to avoid a situation of looseness or poor connection of the interface due to shaking. On the other hand, the appropriate size of the opening can also provide physical protection for the interface unit 120, thereby reducing the possibility of damaging the interface or affecting data transmission because external dust, a foreign object, and the like enters the interface.

In this embodiment, the transformable data storage apparatus further includes a protective cover body 400. The protective cover body 400 is configured to protect the interface unit 120. Through the arrangement of the above structure, the protective cover body 400 can effectively prevent the dust and the foreign object from entering the interface unit 120 during use, to ensure that the interface unit 120 is always kept clean.

In this embodiment, the appendage system 300 includes a first appendage assembly 310 and a second appendage assembly 320. The first appendage assembly 310 is rotatably connected to the side walls 230; and the first appendage assembly 310 is rotatably connected to the side walls 230. Through the arrangement of the above structure, during use, the first appendage assembly 310 and the second appendage assembly 320 can cooperate each other through different design elements such as shape, color, and material in the unfolded state, so as to create a more diverse decorative effect. For example, the first appendage assembly 310 can be designed in a shape of an animal forelimb, and the second appendage assembly 320 can be designed in a shape of an animal hind limb. When being simultaneously unfolded, the two appendage assemblies can be combined into a beautiful animal shape, which increases the aesthetics and aesthetic sense of the transformable data storage apparatus and meets a need of the user for diversification of the decorative function.

In this embodiment, the first appendage assembly 310 includes a first appendage 311 and a second appendage 312. The first appendage 311 is arranged on the third side wall 233. The second appendage 312 is arranged on the fourth side wall 234. Through the arrangement of the above structure, during use, the first appendage 311 and the second appendage 312 are respectively arranged on the third side wall 233 and the fourth side wall 234 which are oppositely arranged, so that a visual range of the apparatus can be expanded in two different directions when the apparatus is unfolded. Compared with the arrangement of an appendage on only one side, this layout can attract the attention in a wider spatial angle and increase the spatial visual presence of transformable data storage apparatus.

In this embodiment, the second appendage assembly 320 includes a third appendage 321 and a fourth appendage 322. The third appendage 321 is arranged at a first end 2321 of the second side wall 232. The fourth appendage 322 is arranged at a second end 2322 of the second side wall 232. Through the arrangement of the above structure, during use, the third appendage 321 and the fourth appendage 322 are respectively located at the two ends of the second side wall 232. This layout can enlarge a distribution range of decorative details. When the appendage system 300 is unfolded, the appendage system 300 is combined with the first appendage assembly 310 to present rich visual elements at different positions and in different angles. For example, when the first appendage assembly 310 is mainly used for vertical decoration that emphasizes the height. The third appendage 321 and the fourth appendage 322 can serve as transverse supplements, so that a spatial decorative image of the entire transformable data storage apparatus is more three-dimensional and fuller, which creates a richer visual hierarchy.

In this embodiment, the transformable data storage apparatus further includes a tail assembly 500. The tail assembly 500 is mounted between the first end 2321 and the second end 2322 of the second side wall 232. Through the arrangement of the above structure, the tail assembly 500 is mounted between the first end 2321 and the second end 2322 of the second side wall 232 during use, which visually fills in the gap in this region. By cooperation with the existing components such as the appendage system 300, the appearance of the transformable data storage apparatus is more balanced and harmonious.

In this embodiment, the tail assembly 500 includes a tail mounting member 510 and a tail piece 520. The tail mounting member 510 is fixedly connected to the second side wall 232. The tail piece 520 is rotatably connected to the tail mounting member 510. Through the arrangement of the above structure, during use, the tail piece 520 can be adjusted to different angles by rotation. The user can change the angle of the tail piece 520 according to a preference or a need of an exhibition environment. This flexibility causes the apparatus to exhibit different decorative styles in different scenarios. For example, in a creative exhibition or personal space, the tail piece 520 can be rotated to a tilting angle to form a staggered shape with the appendage system 300, thereby enhancing the aesthetic sense of the transformable data storage apparatus and meeting diverse aesthetic needs.

In this embodiment, the first appendage 311 includes a first connector 3111. The second appendage 312 includes a second connector 3121. The third appendage 321 includes a third connector 3211. The fourth appendage 322 includes a fourth connector 3221. The first appendage 311 is rotatably connected to the third side wall 233 through the first connector 3111. The second appendage 312 is rotatably connected to the fourth side wall 234 through the second connector 3121. The third appendage 321 is rotatably connected to the second side wall 232 through the third connector 3211. The fourth appendage 322 is rotatably connected to the second side wall 232 through the fourth connector 3221. Through the arrangement of the above structure, the rotatable connection manner allows the user to flexibly adjust the angle and position of the appendage system 300 according to different occasions, moods, or decorative themes during use. The user can create various combinations of shapes to meet the diverse aesthetic needs.

In this embodiment, a rotation center line of the first connector 3111 is a first center line A. A rotation center line of the second connector 3121 is a second center line B. The first center line A approximately overlaps the second center line B. Through the arrangement of the above structure, during use, the first appendage 311 and the second appendage 312 can maintain a symmetrical visual effect during rotation because the first center line A approximately overlaps the second center line B. This symmetry may provide people a harmonious and orderly visual experience, so that the transformable data storage apparatus is more aesthetically pleasing in terms of the decorative function.

In this embodiment, a rotation center line of the third connector 3211 is a third center line C; a rotation center line of the fourth connector 3221 is a fourth center line D; and the third center line C is approximately parallel to the fourth center line D. Through the arrangement of the above structure, the parallel rotation center lines allow the third appendage 321 and the fourth appendage 322 to rotate in different parallel planes during use, thereby providing more diverse combinations of decorative angles. The user can adjust the angles of the appendages in the parallel planes according to the personal preference or the need of the exhibition environment, to create a variety of appearance shapes. For example, the third appendage 321 is adjusted to a slightly upward tilting angle, and the fourth appendage 322 is adjusted to a slightly downward tilting angle, so that the third appendage and the fourth appendage are interwoven with other appendages to form a unique spatial shape, thereby enhancing the artistic expression of the transformable data storage apparatus.

In this embodiment, the third center line C is approximately perpendicular to the first center line A and the second center line B, and the fourth center line D is approximately perpendicular to the first center line A and the second center line B. Through the arrangement of the above structure, the decorative dimension of the transformable data storage apparatus can be enriched during use. Specifically, since the third center line C and the fourth center line D are approximately perpendicular to the first center line A and the second center line B, the rotation planes of the appendages are perpendicular to each other, thereby creating a three-dimensional decorative space. The first appendage 311 and the second appendage 312 rotate in one plane, which provides dynamic decoration in a horizontal direction, and the third appendage 321 and the fourth appendage 322 rotate in one plane perpendicular to them, which adds decorative variations in a vertical direction. This multi-dimensional decorative effect makes the transformable data storage apparatus more vivid and three-dimensional, which is like a piece of artwork with a plurality of movable joints, which can display unique visual effects in different angles and can better attract the attention of viewers.

In this embodiment, the first appendage 311 further includes a first leg piece 3112. The second appendage 312 further includes a second leg piece 3122. The third appendage 321 further includes a third leg piece 3212. The fourth appendage 322 further includes a fourth leg piece 3222. The first leg piece 3112 is rotatably connected to the first connector 3111. The second leg piece 3122 is rotatably connected to the first connector 3111. The third leg piece 3212 is rotatably connected to the third connector 3211. The fourth leg piece 3222 is rotatably connected to the fourth connector 3221. Through the arrangement of the above structure, the leg pieces in the appendages can be rotatably connected during use, so that the shape of each appendage can change itself. The user can create various shapes by adjusting the angles of the leg pieces according to an own creativity and different usage scenarios. For example, during exhibition, the first leg piece 3112 and the second leg piece 3122 can be adjusted to different angles, so that the first appendage 311 and the second appendage 312 are in a bending or extending shape similar to the legs of an animal, and cooperate with other appendages to enhance the biomimetic or artistic decorative effect of the transformable data storage apparatus.

In this embodiment, a plane where the first leg piece 3112 is located always remains approximately perpendicular to the first center line A during rotation. A plane where the second leg piece 3122 is located always remains approximately perpendicular to the second center line B during rotation. The first appendage 311 always remains approximately parallel to a plane where the first appendage 311 is located. Through the arrangement of the above structure, the visual hierarchy and stereoscopic perception of the transformable data storage apparatus can be enhanced during use. Due to a constant relative position between the appendages and the leg pieces during rotation, the spatial positions and angles of the appendages are clearer. This helps to form clear visual hierarchy and stereoscopic perception. For example, when the transformable data storage apparatus is observed in different angles, the user can clearly see the distributions of the appendages on different planes and spatial relationships between the appendages. It is like a well-designed three-dimensional sculpture. The positions and postures of the parts cooperate with each other, thereby enhancing the artistic expression and ornamental value of the transformable data storage apparatus.

In this embodiment, a plane where the third leg piece 3212 is located always remains approximately parallel to the third center line C during rotation, and a plane where the fourth leg piece 3222 is located always remains approximately parallel to the fourth center line D during rotation. Through the arrangement of the above structure, during use, keeping the planes where the leg pieces are located parallel to the center lines helps to enhance the overall style of the transformable data storage apparatus. This parallel relationship makes movements of the third appendage 321 and the fourth appendage 322 visually more regular and uniform. Both a modern minimalist style and a technologically advanced design style can be integrated.

In this embodiment, a spatial degree of freedom of the second appendage assembly 320 is greater than a spatial degree of freedom of the first appendage assembly 310. Through the arrangement of the above structure, the second appendage assembly 320 has a larger spatial degree of freedom during use, which means the second appendage assembly 320 has more possibilities in decorative shapes. The second appendage assembly 320 can have morphological changes in a wider spatial range, to create more complex and diverse decorative shapes than the first appendage assembly.

In this embodiment, a spatial degree of freedom of the first leg piece 3112 is equal to a spatial degree of freedom of the second leg piece 3122. Through the arrangement of the above structure, the symmetry and coordination of the decorative style can be maintained during use. Specifically, the first leg piece 3112 and the second leg piece 3122 have equal spatial degrees of freedom, which makes the two leg pieces have the same possibility in movement and shape change. During decoration, the first leg piece and the second leg piece can keep symmetrical movement states and similar shape changes.

In this embodiment, a spatial degree of freedom of the third leg piece 3212 is equal to a spatial degree of freedom of the fourth leg piece 3222. Through the arrangement of the above structure, the symmetry and coordination of the decorative style can be maintained during use. Specifically, the third leg piece 3212 and the fourth leg piece 3222 have equal spatial degrees of freedom, which makes the two leg pieces have the same possibility in movement and shape change. During decoration, the first leg piece and the second leg piece can keep symmetrical movement states and similar shape changes.

In this embodiment, the spatial degree of freedom of the first leg piece 3112 is less than the spatial degree of freedom of the third leg piece 3212. Through the arrangement of the above structure, rich decorative hierarchy can be created during use. Specifically, the third leg piece 3212 has a larger spatial degree of freedom, so that the third leg piece 3212 can achieve more complex and more diverse changes in the decorative shape. Compared with the first leg piece 3112, the third leg piece 3212 can move in a wider spatial range, thereby achieving a richer decorative effect. For example, when the apparatus is exhibited as a decoration, the first leg piece 3112 has a relatively small movement range due to the limitation of the spatial degree of freedom, so that it mainly achieves auxiliary decoration, such as performing simple swinging or small-angle rotation. The third leg piece 3212 can be extended, bent, or twisted significantly, and can cross different spatial levels to form a sharp contrast with the first leg piece 3112. This contrast can create a distinct and layered decorative effect, just like a painting with primary and secondary roles, attracting the attention of viewers and making the transformable data storage apparatus more artistically charming.

As described above, one or more embodiments are provided in conjunction with the detailed description, The specific implementation of the present disclosure is not confirmed to be limited to that the description is similar to or similar to the method, the structure and the like of the present disclosure, or a plurality of technical deductions or substitutions are made on the premise of the conception of the present disclosure to be regarded as the protection of the present disclosure.

1. A transformable data storage apparatus, comprising:
a data storage system, wherein the data storage system comprises a storage unit and an interface unit; the storage unit is electrically connected to the interface unit; the storage unit is configured to store data; the data storage system is connected to an external device through the interface unit;
an accommodating housing, wherein the accommodating housing comprises a top wall, a bottom wall, and side walls; the side walls comprise a first side wall, a second side wall, a third side wall, and a fourth side wall; the first side wall is opposite to the second side wall, and the third side wall is opposite to the fourth side wall; the top wall, the bottom wall, and the side walls jointly define an accommodating space; the accommodating space is configured to accommodate the data storage system; and
an appendage system, wherein the appendage system is rotatably connected to the accommodating housing; the appendage system has an unfolded state and a stored state; when the appendage system is in the stored state, the appendage system is folded and contracted; and when the appendage system is in the unfolded state, the transformable data storage apparatus has a decorative function.

2. The transformable data storage apparatus according to claim 1, wherein the data storage system is a semiconductor storage system, and the storage unit is a semiconductor chip.

3. The transformable data storage apparatus according to claim 1, wherein the first side wall is provided with a side wall opening; a size of the side wall opening corresponds to the interface unit; and the interface unit is threaded out of the first side wall through the opening.

4. The transformable data storage apparatus according to claim 3, further comprising a protective cover body, wherein the protective cover body is configured to protect the interface unit.

5. The transformable data storage apparatus according to claim 1, wherein the appendage system comprises a first appendage assembly and a second appendage assembly; the first appendage assembly is rotatably connected to the side walls; and the first appendage assembly is rotatably connected to the side walls.

6. The transformable data storage apparatus according to claim 5, wherein the first appendage assembly comprises a first appendage and a second appendage; the first appendage is arranged on the third side wall; and the second appendage is arranged on the fourth side wall.

7. The transformable data storage apparatus according to claim 6, wherein the second appendage assembly comprises a third appendage and a fourth appendage; the third appendage is arranged at a first end of the second side wall; and the fourth appendage is arranged at a second end of the second side wall.

8. The transformable data storage apparatus according to claim 7, wherein the transformable data storage apparatus further comprises a tail assembly; and the tail assembly is mounted between the first end and the second end of the second side wall.

9. The transformable data storage apparatus according to claim 8, wherein the tail assembly comprises a tail mounting member and a tail piece; the tail mounting member is fixedly connected to the second side wall; and the tail piece is rotatably connected to the tail mounting member.

10. The transformable data storage apparatus according to claim 9, wherein the first appendage comprises a first connector; the second appendage comprises a second connector; the third appendage comprises a third connector; the fourth appendage comprises a fourth connector; the first appendage is rotatably connected to the third side wall through the first connector; the second appendage is rotatably connected to the fourth side wall through the second connector; the third appendage is rotatably connected to the second side wall through the third connector; and the fourth appendage is rotatably connected to the second side wall through the fourth connector.

11. The transformable data storage apparatus according to claim 10, wherein a rotation center line of the first connector is a first center line; a rotation center line of the second connector is a second center line; and the first center line approximately overlaps the second center line.

12. The transformable data storage apparatus according to claim 11, wherein a rotation center line of the third connector is a third center line; a rotation center line of the fourth connector is a fourth center line; and the third center line is approximately parallel to the fourth center line.

13. The transformable data storage apparatus according to claim 12, wherein the third center line is approximately perpendicular to the first center line and the second center line; and the fourth center line is approximately perpendicular to the first center line and the second center line.

14. The transformable data storage apparatus according to claim 13, wherein the first appendage further comprises a first leg piece; the second appendage further comprises a second leg piece; the third appendage further comprises a third leg piece; the fourth appendage further comprises a fourth leg piece; the first leg piece is rotatably connected to the first connector; the second leg piece is rotatably connected to the first connector; the third leg piece is rotatably connected to the third connector; and the fourth leg piece is rotatably connected to the fourth connector.

15. The transformable data storage apparatus according to claim 14, wherein a plane where the first leg piece is located always remains approximately perpendicular to the first center line during rotation; a plane where the second leg piece is located always remains approximately perpendicular to the second center line during rotation; and the first appendage always remains approximately parallel to a plane where the first appendage is located.

16. The transformable data storage apparatus according to claim 15, wherein a plane where the third leg piece is located always remains approximately parallel to the third center line during rotation, and a plane where the fourth leg piece is located always remains approximately parallel to the fourth center line during rotation.

17. The transformable data storage apparatus according to claim 10, wherein a spatial degree of freedom of the second appendage assembly is greater than a spatial degree of freedom of the first appendage assembly.

18. The transformable data storage apparatus according to claim 14, wherein a spatial degree of freedom of the first leg piece is equal to a spatial degree of freedom of the second leg piece.

19. The transformable data storage apparatus according to claim 18, wherein a spatial degree of freedom of the third leg piece is equal to a spatial degree of freedom of the fourth leg piece.

20. The transformable data storage apparatus according to claim 19, wherein the spatial degree of freedom of the first leg piece is less than the spatial degree of freedom of the third leg piece.
